(19) United States
(12) Patent Application Publication
(10) Pub. No.: US 2004/0043617 A1
(43) Pub. Date: Mar. 4, 2004

(54) Partitioned wafer boat for constant wafer backside emmissivity

(75) Inventors: Wei-Ming You, Taipei (TW); Hsueh-Li Sun, Yon-Kan City (TW); Jih-Churng Twu, Chia Ho City (TW); Ching-Shan Lu, Tainan (TW); Kuo-Bin Huang, Tainan (TW); Chun-Yi Kuo, Tainan (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/235,139

(22) Filed: Sep. 4, 2002

(51) Int. Cl. H01L 21/302

(52) U.S. Cl. 438/690

(57) ABSTRACT

A wafer boat including a partition which separates vertically adjacent wafer slots in the wafer boat and at least partially shields each wafer from the backside emissivity of the adjacently overlying wafer in order to form oxide layers of substantially uniform thickness on the wafers during thermal oxidation processing. Each of the partitions may be constructed of quartz. In another embodiment, each wafer is at least partially shielded from the backside emissivity of the adjacently overlying wafer by separating or partitioning the wafers using a bare or uncoated wafer.

### FIELD OF THE INVENTION

The present invention relates to processes for forming gate oxides on semiconductor wafer substrates. More particularly, the present invention relates to a new and improved wafer boat which facilitates constant backside emmissivity of multiple semiconductor wafers during a rapid thermal oxidation (RTO) process for improving the thickness uniformity of gate oxide layers among the wafers.

### BACKGROUND OF THE INVENTION

In the semiconductor fabrication industry, silicon oxide (SiO₂) is frequently used for its insulating properties as a gate oxide or dielectric. As the dimensions of device circuits on substrates become increasingly smaller, the gate dielectric thickness must decrease proportionately in field effect transistors (FETs) to approximately 3 to 3.5 nonometers. Accordingly, device performance and reliability can be adversely affected by such factors as interfacial defects, defect precursors and diffusion of dopants through gate dielectrics, as well as unintended variations in thickness in the gate oxide layer.

A current drive in the semiconductor device industry is to produce semiconductors having an increasingly large density of integrated circuits which are ever-decreasing in size. These goals are achieved by scaling down the size of the circuit features in both the lateral and vertical dimensions. Vertical downscaling requires that the thickness of gate oxides on the wafer be reduced by a degree which corresponds to shrinkage of the circuit features in the lateral dimension. While there are still circumstances in which thicker gate dielectrics on a wafer are useful, such as to maintain operating voltage compatibility between the device circuits manufactured on a wafer and the current packaged integrated circuits which operate at a standard voltage, ultrathin gate dielectrics will become increasingly essential for the fabrication of semiconductor integrated circuits in the burgeoning small/fast device technology.

Oxides are grown on wafers by reacting oxygen with silicon in an oxidation furnace to form the silicon dioxide film on the upper wafer surface. Typically, the multiple wafers are supported in vertically-spaced relationship to each other on a wafer boat, which is positioned inside a vertical furnace. Temperatures for the oxidation process may range from 750° C. to 1100° C. and can vary for different oxidation process steps. The furnace temperature at each step is precisely controlled.

Because it is strongly correlated with gate oxide integrity, uniformity in thickness among all regions of the gate oxide layer is a major challenge and concern in ultrathin gate oxide fabrication. Currently, gate oxide thickness grown on wafers has decreased to less than 20 Å in order to achieve enhanced oxide thickness variation control. In general, AP (atmospheric pressure) oxide furnaces are capable of providing a wafer-to-wafer uniformity at around 0.8% on 17 Å nitride film.

During the thermal oxidation process, each wafer absorbs and emits heat radiation. The total emissivity of each wafer depends on a number of factors including the optical properties of the wafer (intrinsic emissivity), the dielectric or conducting layers that may exist on the wafer surface or bottom, buried layers in the wafer (extrinsic emissivity), and the optical properties of the chamber and chamber components (effective emissivity). The wafers contain layers of deposited films and patterns in those films, and these films increase the emissivity of the wafers. Parameters which affect the extrinsic emissivity of each wafer include front and backside film thickness, material optical properties, and etched features. It has been found that, on multiple wafers in an oxidation processing chamber, oxide films having a thickness of less than 30 Å, and particularly, less than 20 Å, will manifest variations in oxide growth rates due to variations in backside emmissivity among the wafers. The thickness of the oxide layer grown on the top surface of each wafer is proportional to the backside emissivity of a wafer positioned directly above the wafer in the wafer boat. For example, wafers coated with TEOS film induced a higher oxide growth rate on the top surface of underlying wafers than did bare silicon wafers during ultra thin oxide processing. Because backside emmissivity of one wafer may contribute to between 2% and 5% (0.8 Å to 1 Å) variation in thickness of a film on a wafer beneath the wafer, it is important to control backside emmissivity of wafers in an AP furnace in order to prevent or reduce as much as possible variations in oxide growth rates among wafers in the same batch.

FIG. 1 illustrates a conventional arrangement of multiple W.I.P. (work-in-progress) wafers 18 on a wafer boat 10 for forming an oxide layer on the upper surface of each of the wafers 18 in a vertical thermal processing chamber (not shown). The wafer boat 10 includes a frame 12, from which multiple wafer supports 14 extend and define vertically-spaced wafer slots 16. As many as 150 wafers 18 are inserted in the respective wafer slots 16 and are supported on the wafer supports 14 during processing. In a previous processing step, each of the wafers 18 is typically coated with a film such as PLOY2000A, TEOS1000A, SIN1625A or Thermal OX 1050A, for example, within which film device features are formed. The film-coated wafers 18 are contained in respective vertically-adjacent wafer slots 16 in the wafer boat 10. During thermal processing, the wafers 18 are heated to a temperature of typically about 750° C. to 1100° C. to deposit an oxide film on the upper surface of each of the wafers 18. The thermal processing of the wafers 18 causes emission of thermal radiation from the backside of each wafer, and the backside emissivity of each wafer 18 varies according to the type of film on the wafer 18.

The backside emissivity contributed by the film on each of the wafers 18 causes deposition of a thicker or thinner layer of oxide on the top surface of the wafer 18 in the adjacently underlying wafer slot 16 than would otherwise be the case for a wafer 18 underlying a bare silicon wafer (not shown) in the wafer boat 10. This effect is shown in the graph of FIG. 2, in which the thickness of an oxide layer formed on the surface of each of multiple wafers in a wafer boat is plotted along the Y-axis. Wafers in consecutive wafer slots in the wafer boat are plotted along the X-axis. As shown in the graph, the oxide layer grown on each multiple wafers indicated by the circles is thicker than the oxide layer grown on each of multiple wafers indicated by the triangles. The thicker oxide layer on each of the wafers represented by the circles is due to the higher backside emissivity of a film-coated wafer located in the wafer slot immediately above the thicker-oxide wafer.

The variations in backside emissivity caused by the film on the wafers contributes to wide variations in oxide thicknesses among wafers in a single batch during thermal oxidation processing. For example, in a recent experiment in which the target thickness for the oxide layer on each wafer was 19.5, the TEOS1000A wafer was found to have a backside emissivity of 0.79, as compared to a bare wafer, which has a backside emissivity of 0.67. The higher backside emissivity of the TEOS1000A wafer results in an underlying wafer having an oxide thickness of 19.7, which is thicker than the target thickness. The Ploy2000A wafer, on the other hand, has a backside emissivity of 0.61, and this results in an underlying wafer having an oxide thickness of 19.12 angstroms, which is thinner than the target thickness. The bare wafer, having a backside emissivity of 0.67, results in an underlying wafer having an oxide thickness of about 19.22. Accordingly, a device is needed for achieving more uniform oxide thicknesses on film-coated wafers in a single batch during thermal oxidation.

### SUMMARY OF THE INVENTION

In accordance with these and other objects and advantages, the present invention comprises a wafer boat including a partition which separates vertically adjacent wafer slots in the wafer boat and at least partially shields each wafer from the backside emissivity of the adjacently overlying wafer in order to form oxide layers of substantially uniform thickness on the wafers during thermal oxidation processing. Each of the partitions may be constructed of quartz. In another embodiment, each wafer is at least partially shielded from the backside emissivity of the adjacently overlying wafer by separating or partitioning the wafers using a bare or uncoated wafer.

An object of the present invention is to provide a device for providing a stable oxidation environment for deposition of oxide layers having uniform thicknesses on multiple semiconductor wafers in a batch during thermal oxidation.

Another object of the present invention is to provide a new and improved wafer boat which contributes to enhanced uniformity in oxide layer thickness on multiple semiconductor wafers in a single batch during thermal oxidation processing.

Still another object of the present invention is to provide a mechanism for shielding each of multiple wafers from the backside emissivity of an adjacently overlying wafer in a wafer boat during thermal oxidation of the wafers in order to achieve oxide layers of substantially uniform thickness among the wafers.

Yet another object of the present invention is to provide a new and improved, partitioned wafer boat including multiple wafer slots each of which is separated from adjacent underlying and overlying wafer slots by a partition which shields each wafer from the backside emissivity of the overlying wafer and enhances uniformity in the thickness of oxide layers formed on the wafers.

A still further object of the present invention is to provide a method of forming oxide layers of substantially uniform thickness on multiple wafers during thermal oxidation of the wafers.

Yet another object of the present invention is to provide a method of substantially reducing variations in the thickness of oxide layers on multiple wafers during thermal oxidation of the wafers by separating vertically adjacent wafers with a bare or uncoated wafer.

Another object of the present invention is to provide a method of substantially reducing variations in the thickness of oxide layers on multiple wafers during thermal oxidation of the wafers by providing a partition between vertically adjacent wafers during thermal processing.

### BRIEF DESCRIPTION OF THE DRAWINGS

The invention will now be described, by way of example, with reference to the accompanying drawings, in which:

FIG. 1 illustrates a section of a conventional wafer boat and a conventional arrangement of wafers in the wafer boat for thermal oxidation of the wafers;

FIG. 2 is a graph illustrating variations in thickness of oxide layers formed on wafers as a result of variations in backside emissivity among the wafers using a conventional arrangement of wafers in the conventional wafer boat;

FIG. 3 illustrates a section of a wafer boat with wafers arranged in the wafer boat according to a method of the present invention for forming oxide layers of substantially uniform thickness on the wafers;

FIG. 3A is a sectional view of a wafer of FIG. 3, with an oxide layer formed on the upper surface of the wafer;

FIG. 4 is a graph illustrating substantially uniform thicknesses of oxide layers formed on multiple wafers by at least partially shielding each wafer from the backside emissivity of the adjacent wafer;

FIG. 5 illustrates a section of a partitioned wafer boat of the present invention; and

FIG. 5A is a sectional view of a wafer of FIG. 5, with an oxide layer formed on the upper surface of the wafer.

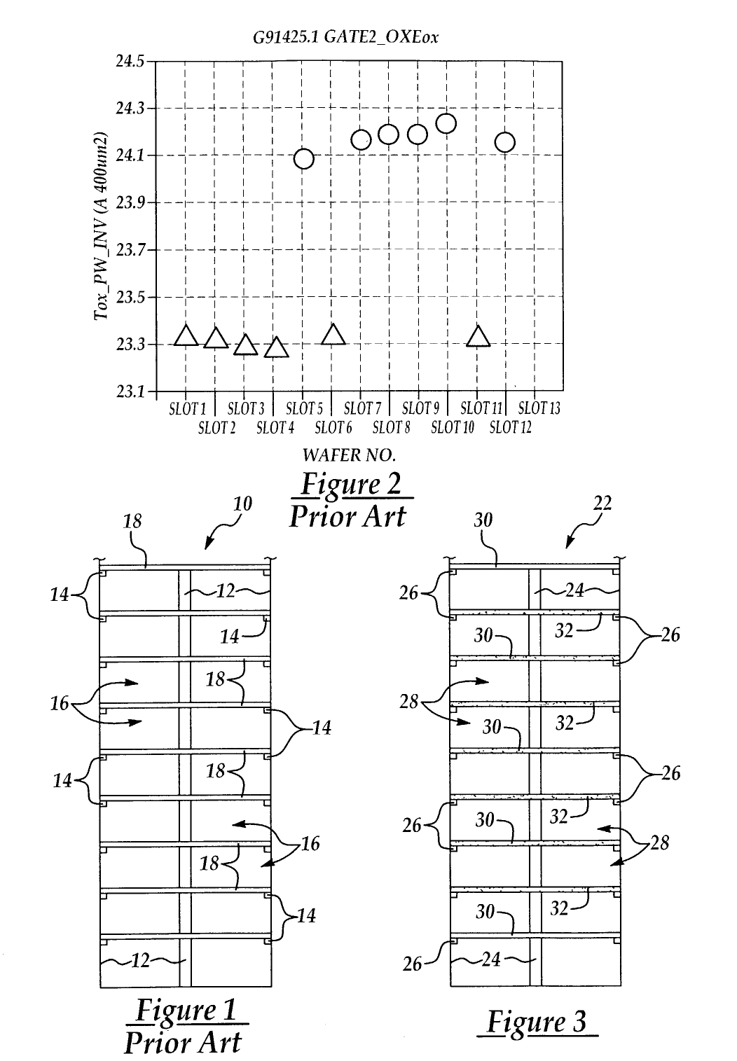

### DESCRIPTION OF THE PREFERRED EMBODIMENTS

In one embodiment, the present invention comprises a new and improved, partitioned wafer boat for at least partially shielding wafers from the backside emissivity of overlying wafers in order to compensate for variations in backside emissivity among wafers which otherwise contributes to variations in thickness of oxide layers formed on the wafers during thermal oxidation. An illustrative embodiment of the partitioned wafer boat of the present invention is generally indicated by reference numeral 36 in FIG. 5, and includes an elongated, vertical frame 38. Wafer supports 40 extending inwardly from the frame 38 define multiple vertically-adjacent wafer slots 42 for receiving respective WIP (work in progress) wafers 46, each of which rests on a set of wafer supports 40 in the corresponding wafer slot 42 in application of the partitioned wafer boat 36 as hereinafter described. Wafer partitions 44 mounted on the frame 38 separate adjacent wafer slots 42 in the wafer boat 36. The wafer partitions 44 may be removably or fixedly mounted on the frame 38. The space between each wafer partition 44 and the adjacently underlying wafer support 40, indicated by the letter “A” in FIG. 5, is typically about 5.2 mm, whereas the space between each wafer partition 44 and the adjacently overlying wafer support 40, indicated by the letter “B”, is typically in the range of about 0.5 mm to about 2 mm. Each wafer partition 44 may be constructed of glass, typically quartz, and may have a thickness of about 2-5 μm.

In application, the partitioned wafer boat 36 is placed in a vertical oxidation furnace (not shown), wherein the WIP wafers 46 are subjected to thermal oxidation processing, according to parameters known by those skilled in the art. During the thermal oxidation process, each of the wafer partitions 44 shields the WIP wafer 46 in the underlying wafer slot 42 from the backside emissivity of the WIP wafer 46 in the wafer slot 42 above the shielded WIP wafer 46. Consequently, the thickness of an oxide layer 48 formed on the upper surface of each WIP wafer 46, as shown in FIG. 5A, is substantially the same as the thickness of the oxide layer 48 formed on the upper surface of the other WIP wafers 46 in the same batch in the partitioned wafer boat 36.

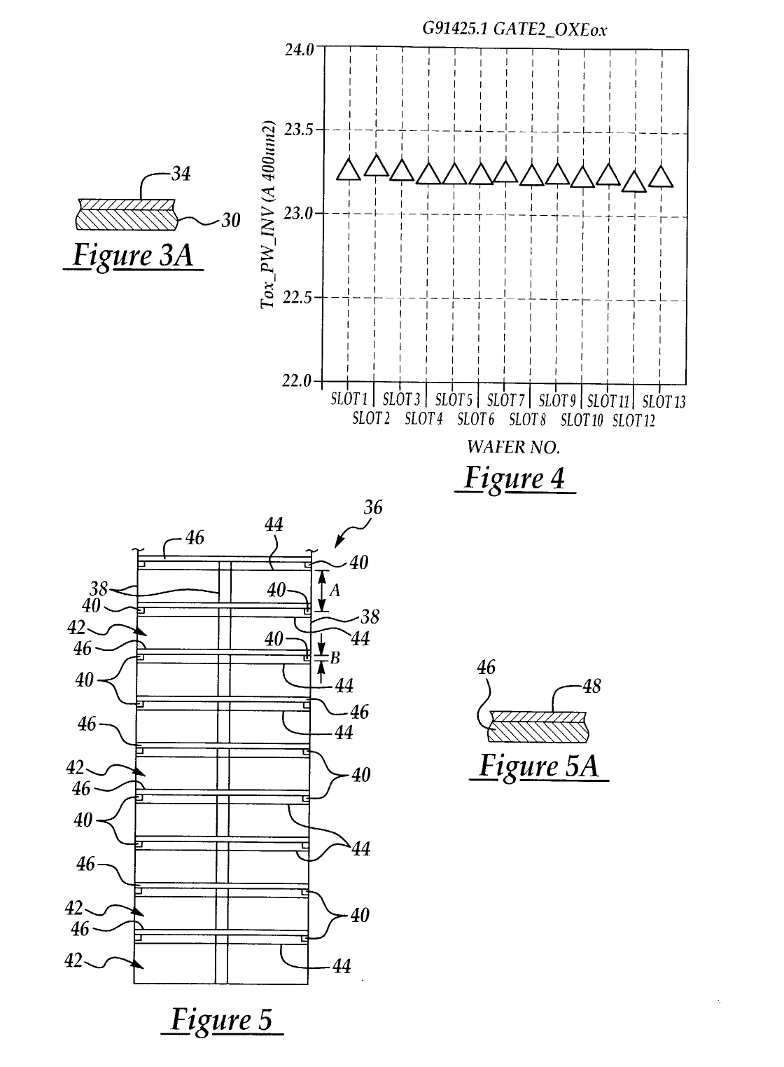

In another embodiment, the present invention comprises a method of reducing or eliminating variations in thickness of oxide layers on wafers during thermal oxidation processing by novel arrangement of wafers in a wafer boat. This method of the present invention is illustrated in FIG. 3, in which a conventional wafer boat is generally indicated by reference numeral 22. The wafer boat 22 includes an elongated, vertical frame 24 which is fitted with wafer supports 26 that define as many as 150 or more vertically-adjacent wafer slots 28. According to a method of the present invention, alternating ones of the wafer slots 28 in the wafer boat 22 each receives a bare, uncoated dummy silicon wafer 32, which is further indicated by the mottled appearance in FIG. 3, with each dummy wafer 32 resting on the wafer supports 26 of the corresponding wafer slot 28. A WIP (work in progress) wafer 30, which may be an epitaxial wafer or a wafer coated with a film for the fabrication of integrated circuits on the upper surface of the wafer 30, is placed in the remaining wafer slots 28, between the dummy wafers 32, as illustrated.

In application, the WIP wafers 30 are subjected to thermal oxidation processing in a vertical oxidation furnace (not shown), according to parameters known by those skilled in the art, to form an oxide layer 34 on the upper surface of each WIP wafer 30, as shown in FIG. 3A. Each bare dummy wafer 32 shields the upper surface of each underlying WIP wafer 30 from the backside emissivity of the WIP wafer 30 which overlies the dummy wafer 32 and would otherwise cause fluctuations or variations in the thickness of the oxide layers among the batch of WIP wafers 30 in the wafer boat 36, were the WIP wafers 30 not separated by the bare dummy wafers 32.

FIG. 4 illustrates a graph wherein the thickness (in angstroms) of the oxide layer formed on each of multiple epitaxial wafers during thermal oxidation processing is plotted along the Y-axis and the position of each epitaxial wafer in the wafer boat is plotted along the X-axis. Each bare dummy wafer had a backside emissivity of 0.67, whereas each epitaxial wafer had an enhanced backside emissivity of 0.818. It can be seen from the graph that the thickness of the oxide layer among the epitaxial wafers is substantially uniform since each of the bare dummy wafers between adjacent epitaxial wafers acts as a partition which shields each epitaxial wafer from the backside emissivity of the overlying epitaxial wafer.

While the preferred embodiments of the invention have been described above, it will be recognized and understood that various modifications can be made in the invention and the appended claims are intended to cover all such modifications which may fall within the spirit and scope of the invention.

Having described our invention with the particularity set forth above, we claim:

1. A wafer boat for holding wafers in a furnace, comprising:
a frame having at least two wafer slots for receiving the wafers, respectively; and
a partition separating adjacent ones of said at least two wafer slots from each other.

2. The wafer boat of claim 1 wherein said partition comprises glass.

3. The wafer boat of claim 1 wherein said partition is about 2-5 μm thick.

4. The wafer boat of claim 3 wherein said partition comprises glass.

5. The wafer boat of claim 2 wherein said glass comprises quartz.

6. The wafer boat of claim 5 wherein said partition is about 2-5 μm thick.

7. The wafer boat of claim 1 wherein said partition is fixedly attached to said frame.

8. The wafer boat of claim 7 wherein said partition comprises glass.

9. The wafer boat of claim 7 wherein said partition is about 2-5 μm thick.

10. The wafer boat of claim 9 wherein said partition comprises glass.

11. The wafer boat of claim 8 wherein said glass comprises quartz.

12. The wafer boat of claim 11 wherein said partition is about 2-5 μm thick.

13. A wafer boat for holding wafers in a furnace, comprising:
a frame having at least two wafer slots for receiving the wafers, respectively;
an upper set of wafer supports extending from said frame for supporting one of the wafers in an upper one of said at least two wafer slots;
a lower set of wafer supports extending from said frame for supporting another of the wafers in a lower one of said at least two wafer slots; and
a partition separating said upper one of said at least two wafer slots from said lower one of said at least two wafer slots.

14. The wafer boat of claim 13 wherein said upper set of wafer supports is separated from said partition by a space of from about 0.5 mm to about 2 mm.

15. The wafer boat of claim 13 wherein said lower set of wafer supports is separated from said partition by a space of about 5.2 mm.

16. The wafer boat of claim 15 wherein said upper set of wafer supports is separated from said partition by a space of from about 0.5 mm to about 2 mm.

17. The wafer boat of claim 13 wherein said partition is from about 2 mm to about 5 mm thick.

18. The wafer boat of claim 17 wherein said lower set of wafer supports is separated from said partition by a space of about 5.2 mm.

19. The wafer boat of claim 17 wherein said upper set of wafer supports is separated from said partition by a space of from about 0.5 mm to about 2 mm.

20. A method of enhancing uniformity in oxide layer thickness on WIP wafers, comprising the steps of:
providing a wafer boat comprising at least three wafer slots;
placing bare dummy wafers in alternating ones of said at least three wafer slots, respectively;
placing a WIP wafer in one of said at least three wafer slots between said bare dummy wafers;
placing said wafer boat in a furnace; and
subjecting said WIP wafer to a thermal oxidation process in said furnace.
